(19) United States
(12) Patent Application Publication
(10) Pub. No.: US 2024/0091759 A1
(43) Pub. Date: Mar. 21, 2024

(54) METHOD OF DEPOSITING TRANSITION METAL SINGLE-ATOM CATALYST

(71) Applicant: KOREA INSTITUTE OF SCIENCE AND TECHNOLOGY, Seoul (KR)

(72) Inventors: Jong Min KIM, Seoul (KR); Sang Hoon KIM, Seoul (KR); Chang Kyu HWANG, Seoul (KR); Seung Yong LEE, Seoul (KR); So Hye CHO, Seoul (KR); Jae Won CHOI, Seoul (KR)

(73) Assignee: KOREA INSTITUTE OF SCIENCE AND TECHNOLOGY, Seoul (KR)

(21) Appl. No.: 18/468,625

(22) Filed: Sep. 15, 2023

(30) Foreign Application Priority Data
Sep. 16, 2022 (KR) 10-2022-0116937

(51) Int. Cl. B01J 37/34; B01J 21/18; B01J 37/02

(52) U.S. Cl. CPC B01J 37/349; B01J 21/18; B01J 37/0217

(57) ABSTRACT

Disclosed herein is a method of depositing a transition metal single-atom catalyst including preparing a carbon carrier, and depositing a transition metal single-atom catalyst on the carbon carrier, in which the carbon carrier is surface-treated by an oxidation process, and wherein the deposition is carried out by an arc plasma process.

### DESCRIPTION ABOUT NATIONAL RESEARCH AND DEVELOPMENT SUPPORT

This study was supported by the technology development program of Ministry of Science and ICT, Republic of Korea (Projects No. 21041100) under the superintendence of National Research Foundation of Korea.

### CROSS REFERENCE TO RELATED APPLICATION

This application claims the benefit under 35 USC 119(a) of Korean Patent Application No. 10-2022-0116937 filed Sep. 16, 2022, in the Korean Intellectual Property Office, the entire disclosure(s) of which is(are) incorporated herein by reference for all purposes.

### BACKGROUND OF THE INVENTION

### Field of the Invention

The present disclosure relates to a method of depositing a transition metal single-atom catalyst, and more particularly, to a method of forming a pure single-atom catalyst in high concentration on a catalyst carrier surface by arc plasma deposition.

### Description of the Related Art

Research on electrochemical energy storage and conversion technologies to produce sustainable and renewable energy has been continuously advancing and growing in importance.

Among others, metal-carried form of catalysts are widely used in various industries due to their high activity, selectivity, and stability, and research is being conducted to highly disperse metals into small sizes to maximize the utilization of expensive metals, and many advanced clean energy technologies such as fuel cells, metal-air batteries, water electrolysis, etc. require highly active catalysts to lower energy barriers and increase reaction rates in an efficient and stable pathway.

Meanwhile, various metal materials (precious metals, transition metals, etc.) mainly used in high-activity catalysts have limited reserves and high prices. Therefore, there is a demand for economically cost-effective catalyst production with high efficiency using small amounts of catalysts.

To solve this problem, research on single-atom catalysts is being actively pursued. the single-atom catalyst refer to a catalyst where individual metal atoms are carried on a surface of a support. These single-atom catalysts exhibit unique catalytic activities due to not only the high dispersion of metal atoms but also distinct properties compared to conventional metal catalysts.

In addition, these single-atom catalysts can maximize specific catalytic activity and have attracted much attention due to their high reaction selectivity in specific reactions (e.g., two-electron oxygen reduction reaction) compared to catalysts in the form of nanoparticles or nanoclusters.

### DOCUMENTS OF RELATED ART

(Patent Document 1) Korean Patent No. 10-2188587
(Patent Document 2) Korean Patent No. 10-2260303
(Patent Document 3) Korean Patent No. 10-2247287

### SUMMARY OF THE INVENTION

Metals at a single-atom size are highly unstable due to a tendency to aggregate to maximize their surface energy. Therefore, the single-atom sized metal catalysts can be synthesized only by using a catalyst carrier that is capable of stabilizing the metal even at the single-atom size due to a strong bond with the metal.

In addition, the catalyst carrier is mostly carbon and an insulator or ceramic, which can bind strongly to the metals and stabilize them even at the single-atom size. In case of a carbon carrier, various processes are used to induce surface defects or the formation of functional groups to ensure that single-atom catalysts are well bound to the surface of the carrier. Due to the high mechanical strength of the ceramic carrier, a top-down approach method has been used to introduce metal atoms by adsorbing the metal atoms and then introducing intense energy (e.g., ball mill).

However, the insulator or ceramic carrier have low electrical conductivity and are unstable under electrochemical conditions, making it almost impossible to apply the single-atom sized metal catalysts carried on these carriers to an electrochemical reaction.

In particular, a representative method that is commonly known for carrying single-atom catalysts on various carriers is to disperse a metal precursor uniformly on the carrier through a solution process and then synthesize the metal precursor using a heat treatment or a reducing agent.

However, this method requires a heat treatment process in the process of reducing the metal precursor, and there are many difficulties because the catalyst is easily aggregated and forms clusters or nanoparticles instead of single-atoms.

In addition, the metal precursor is more expensive compared to a pure single bulk metal, and there are various problems in that the precursor contains salts, which can lead to impurities in the catalyst after synthesis.

For example, a method described in Patent Document 1 uses a transition metal precursor for a transition metal single-atom catalyst, which has the disadvantage of being economically unviable due to the high cost of the transition metal and the complexity of the process.

In addition, a method described in Patent Document 2 uses a precursor and a polyol solvent to prepare a single-atom catalyst, which is then subjected to various complicated processes such as a heat treatment and an acid treatment at a high temperature for reduction and removal of organic matter, but it has the disadvantage in that the catalyst is easily aggregated and formed in the form of clusters or nanoparticles rather than single-atoms, making it difficult to use as a single-atom catalyst.

In addition, a method described in Patent Document 3 uses a precursor to prepare a single-atom catalyst and performs a heat treatment between 300 and 1000° C. to reduce the precursor, but this also has a problem in that the catalyst is easily aggregated during the high heat treatment process and is formed in the form of clusters or nanoparticles rather than single-atoms.

Therefore, there is a demand for a method to manufacture a single-atom catalyst without any additional process.

In order to achieve the above-described technical objects, the present disclosure is directed to providing a method of depositing a transition metal single-atom catalyst including preparing a carbon carrier, and depositing a transition metal single-atom catalyst on the carbon carrier, in which the carbon carrier is surface-treated by an oxidation process, and wherein the deposition is carried out by an arc plasma process.

In addition, a defect is formed on a surface of the carbon carrier by the surface treatment, and the transition metal single-atom catalyst is deposited at a position of the defect.

In addition, the carbon carrier according to the present disclosure may include one or more species selected from graphene, graphene oxide, fullerene, carbon nanotubes, carbon nanofibers, carbon nanobelts, carbon nano onions, carbon nanohorns, activated carbon, graphite, carbon black, and carbon oxide.

In addition, the carbon carrier according to the present disclosure may have a structure of one or more species selected from spherical, rod-type, tubular, horn-type, plate-type, and porous substrates.

In addition, the surface oxidation may be carried out by any one of electrochemical oxidation, oxygen plasma oxidation, and acid treatment.

In addition, the transition metal according to the present disclosure may be any one of cobalt, manganese, nickel, iron, rhodium, and iridium.

In addition, the arc plasma deposition according to the present disclosure may be carried out using an arc discharge voltage between 50 to 200 V, and 1 to 30 pulse shots.

In addition, the present disclosure may provide a transition metal single-atom catalyst carried on the carbon carrier prepared by the method of depositing that is described above.

The present disclosure discloses that various transition metals can be prepared as a single-atom form of catalyst using an arc plasma deposition technology, and that the formation morphology and density of the catalyst can be controlled by controlling an applied voltage and a pulse shot in the arc plasma deposition process.

### BRIEF DESCRIPTION OF THE DRAWINGS

FIG. 1 is a schematic view illustrating a method of surface-treating a carbon carrier according to an embodiment of the present disclosure.

FIG. 2A and FIG. 2B are SEM images illustrating a surface of the carbon carrier that has been surface-treated according to an embodiment of the present disclosure.

FIG. 3 is a conceptual view schematically illustrating a method of depositing a transition metal single-atom catalyst through an arc plasma process, according to an embodiment of the present disclosure.

FIG. 4A and FIG. 4B are TEM images of a catalyst on which single atoms of cobalt have been deposited through arc plasma deposition on the carbon carrier according to an embodiment of the present disclosure.

FIG. 5 is a graph illustrating results of an extended X-ray absorption fine structure (EXAFS) analysis of a catalyst prepared according to an embodiment of the present disclosure.

### DETAILED DESCRIPTION OF THE INVENTION

Hereinafter, a method of depositing a transition metal single-atom catalyst according to a preferred embodiment of the present disclosure will be described with reference to the accompanying drawings.

Prior to the description, unless explicitly described to the contrary, the word “comprise” or “include” and variations, such as “comprises”, “comprising”, “includes” or “including”, will be understood to imply the inclusion of stated constituent elements, not the exclusion of any other constituent elements.

In addition, in the various embodiments, the constituent elements having the same constitution will be described using the same reference numerals, typically in an embodiment, and only different constituent elements will be described in other embodiments.

Further, while the embodiments of the present disclosure have been described with reference to the accompanying drawings, they are described for illustrative purposes only and are not intended to limit the technical spirit of the present disclosure and the constitution and application thereof.

As described above, the present disclosure provides a method of preparing a catalyst by depositing a transition metal in a single-atom form on a surface-treated carbon carrier using an arc plasma deposition method.

To this end, in the present disclosure, a transition metal single-atom catalyst is deposited on a carbon carrier that has been surface-treated by oxidation through an arc plasma process, and is capable of being integratedly deposited using a transition metal target without the use of a precursor or an organic material or the like.

As described above, in case of the single-atom catalyst, due to a unique structure in which an active point of the catalyst is atomic in size, a manner in which reactants are adsorbed on an active surface of the catalyst in an electrochemical reaction is different from other reported catalysts (catalysts with a structure above the cluster form), thereby making it easier to induce a desired reaction.

More specifically, the present disclosure will be described with reference to specific embodiments below.

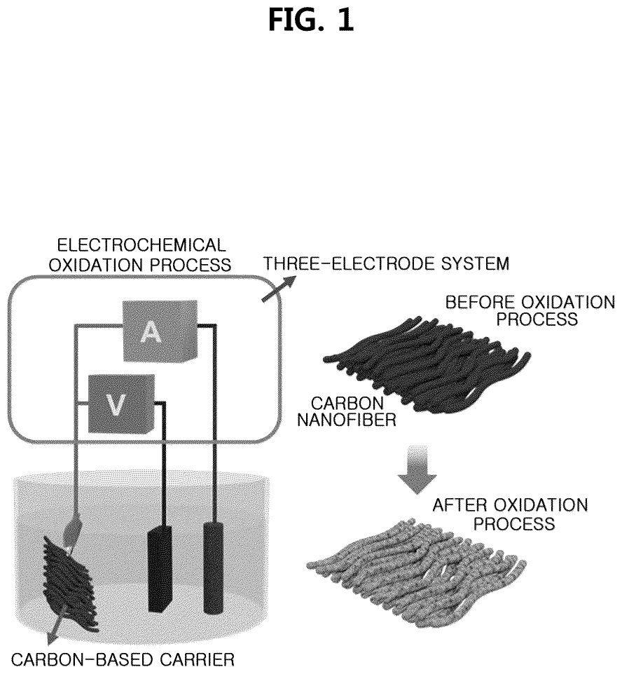

FIG. 1 is a schematic view illustrating a method of surface-treating a carbon carrier according to an embodiment of the present disclosure.

As illustrated in FIG. 1, as a carbon carrier for depositing the transition metal single-atom, it is possible to use a carrier having various structures of one or more species selected from spherical, rod-type, tube-type, horn-type, plate-type, and porous substrates.

Additionally, the carbon carrier may use various materials of one or more species selected from graphene, graphene oxide, fullerene, carbon nanotube (CNT), carbon nanofiber, carbon nanobelt, carbon nano onion, carbon nanohorn, activated carbon, graphite, carbon black, and carbon oxide.

In addition, in order to deposit a high density of single atom onto the carbon carrier, a surface of the carbon carrier needs to be treated with oxidation, which may be achieved by any one of electrochemical oxidation, oxygen plasma oxidation, or acid treatment.

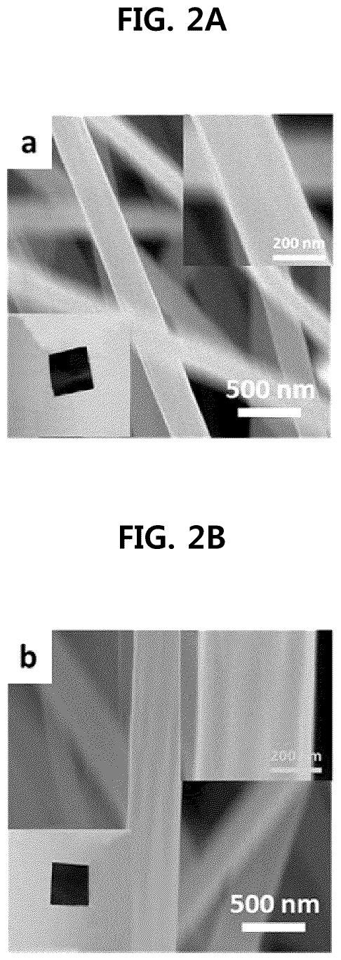

FIG. 2A and FIG. 2B are SEM images illustrating a surface of the carbon carrier that has been surface-treated according to an embodiment of the present disclosure.

As illustrated in FIG. 2A and FIG. 2B, when the surface of the carbon carrier is treated with oxidation, defects are formed on the surface of the carbon carrier, and the transition metal single-atom catalyst is deposited at positions of these defects. Therefore, it is possible to implement a uniform, dense carrier of the single-atom catalyst by maximizing the number of defects.

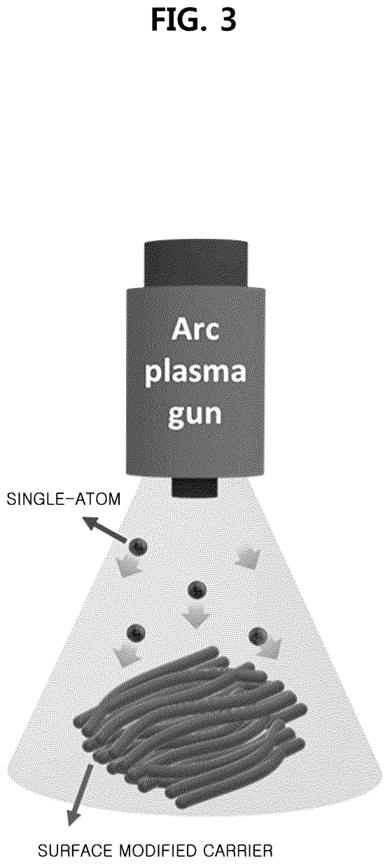

FIG. 3 is a conceptual view schematically illustrating a method of depositing a transition metal single-atom catalyst through an arc plasma process, according to an embodiment of the present disclosure.

As illustrated in FIG. 3, the single-atom catalyst may be prepared on the surface-treated carbon carrier through the arc plasma deposition.

Specifically, the arc plasma deposition is a type of physical vapor deposition process technology in which a current is applied in a vacuum chamber, and a trigger pulse induces an electrical discharge on a surface of a transition metal rod to generate a highly ionized metal plasma to prepare transition metal particles, and the prepared transition metal particles are deposited on a support.

The transition metal may be any one of cobalt, manganese, nickel, iron, rhodium, and iridium, and in this embodiment, cobalt was used.

In addition, the arc plasma deposition is a discontinuous deposition process in which a deposition occurs with each pulse. A deposition amount of transition metal particles can be controlled very precisely by controlling an applied voltage and a pulse shot, and in an embodiment of the present disclosure, a single-atom catalyst was formed by controlling an arc discharge voltage between 50 to 200 V and 1 to 30 pulse shots to prepare the single-atom catalyst.

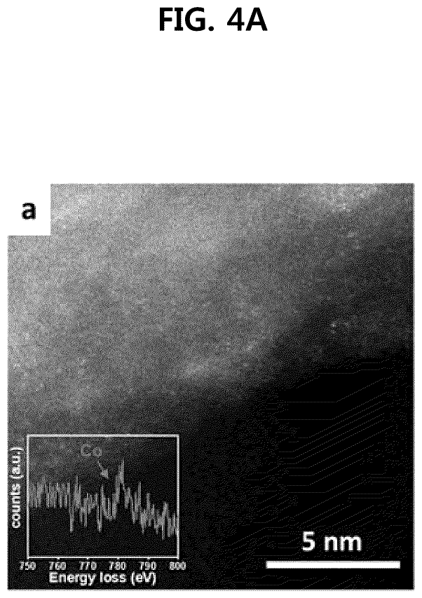

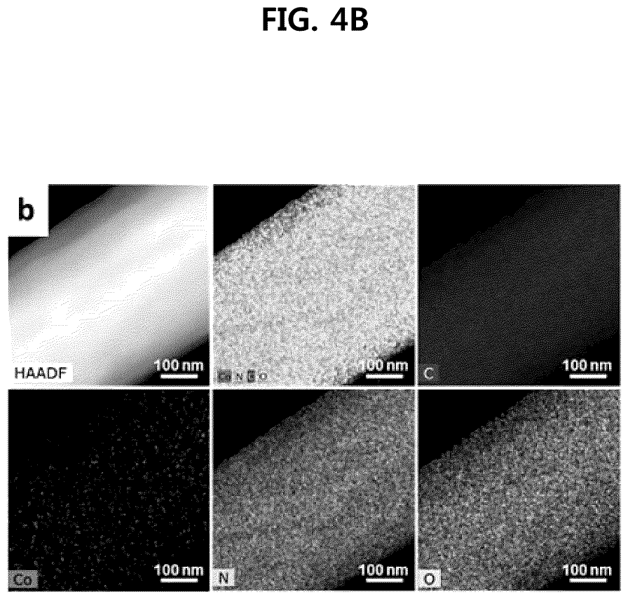

FIG. 4A and FIG. 4B are TEM images of a catalyst on which single atoms of cobalt have been deposited through arc plasma deposition on the carbon carrier according to an embodiment of the present disclosure.

Specifically, the deposition of cobalt on carbon nanofibers has been analyzed by STEM and TEM EDS mapping using an embodiment of the present disclosure.

As illustrated in FIG. 4A and FIG. 4B, it can be seen that cobalt single atoms are uniformly deposited on a surface of the carbon nanofiber carrier, TEM EDS mapping results provide information on various elements constituting the catalyst, and the cobalt element is constituted by single atoms.

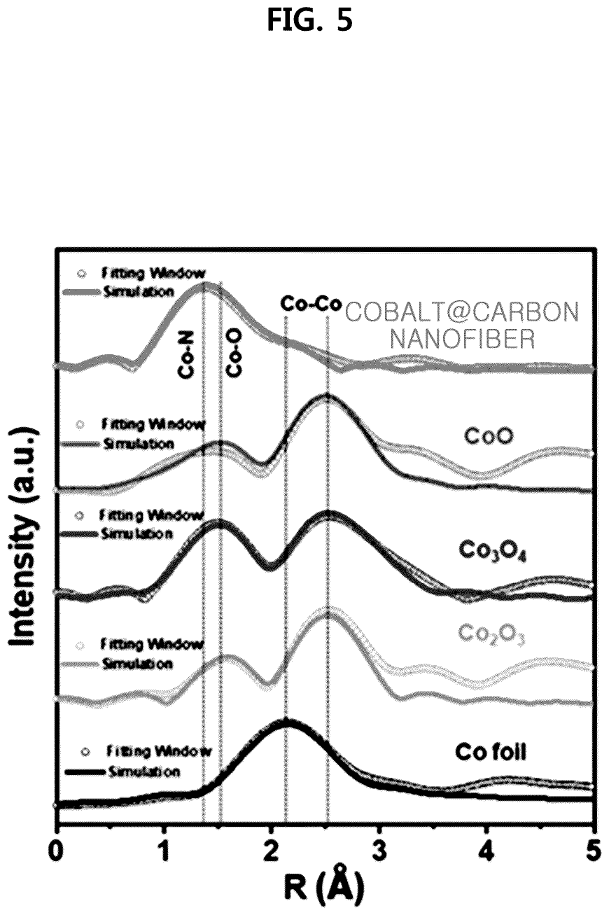

FIG. 5 is a graph illustrating results of an extended X-ray absorption fine structure (EXAFS) analysis of a catalyst prepared according to an embodiment of the present disclosure.

Specifically, EXAFS analysis results of the catalyst with cobalt single atoms deposited on the carbon nanofibers by the arc plasma deposition process are presented.

As illustrated in FIG. 5, it can be seen that bonding peaks between a bulk form of cobalt and cobalt disappear, and only peaks due to the bonding of cobalt single atoms with oxygen and nitrogen are present, as cobalt single atoms are formed on the surface of the catalyst.

With reference to the aforementioned description, those skilled in the art to which the present disclosure belongs will understand that the present disclosure may be carried out in other specific forms without changing the technical spirit or essential characteristics of the present disclosure.

Accordingly, it is to be understood that the embodiments described above are illustrative in all respects and are not intended to limit the present disclosure to the embodiments, and the scope of the present disclosure is indicated by the patent claims which are hereinafter recited rather than by the foregoing detailed description, and the meaning and scope of the patent claims and all modifications or variations derived from the equivalent concepts should be interpreted to be included within the scope of the present disclosure.

What is claimed is:

1. A method of depositing a transition metal single-atom catalyst comprising:
preparing a carbon carrier; and
depositing a transition metal single-atom catalyst on the carbon carrier,
wherein the carbon carrier is surface-treated by an oxidation process, and
wherein the deposition is carried out by an arc plasma process.

2. The method of claim 1, wherein a defect is formed on a surface of the carbon carrier by the surface treatment, and the transition metal single-atom catalyst is deposited at a position of the defect.

3. The method of claim 2, wherein the carbon carrier comprises one or more species selected from graphene, graphene oxide, fullerene, carbon nanotubes, carbon nanofibers, carbon nanobelts, carbon nano onions, carbon nanohorns, activated carbon, graphite, carbon black, and carbon oxide.

4. The method of claim 2, wherein the carbon carrier has a structure of one or more species selected from spherical, rod-type, tubular, horn-type, plate-type, and porous substrates.

5. The method of claim 2, wherein the oxidation process is carried out by any one of electrochemical oxidation, oxygen plasma oxidation, and acid treatment.

6. The method of claim 2, wherein the transition metal is any one of cobalt, manganese, nickel, iron, rhodium, and iridium.

7. The method of claim 2, wherein the arc plasma deposition is carried out using an arc discharge voltage between 50 to 200 V, and 1 to 30 pulse shots.
